(19) United States
(12) Patent Application Publication
(10) Pub. No.: US 2026/0058626 A1
(43) Pub. Date: Feb. 26, 2026

(54) COMPOSITE FILTER AND COMMUNICATION DEVICE

(71) Applicant: KYOCERA Corporation, Kyoto-shi, Kyoto (JP)

(72) Inventor: Junichiro TAKIKAWA, Nara-shi, Nara (JP)

(73) Assignee: KYOCERA Corporation, Kyoto-shi, Kyoto (JP)

(21) Appl. No.: 19/106,260

(22) PCT Filed: Aug. 22, 2023
(86) PCT No.: PCT/JP2023/030096

§ 371 Date: Feb. 25, 2025

(30) Foreign Application Priority Data
Aug. 26, 2022 (JP) 2022-134808

(51) Int. Cl. H03H 7/01; H01Q 1/24; H03H 7/18; H03H 9/48

(52) U.S. Cl. CPC H03H 7/0115; H01Q 1/24; H03H 7/18; H03H 9/48

(57) ABSTRACT

In a composite filter, first to third filters are connected to any ports of a first hybrid including a 90° hybrid coupler. The first filter has a first passband. The second filter and the third filter have a second passband that does not overlap the first passband. An electrical section from the first filter to the first hybrid is referred to as a first part. A combination of an electrical section from the second filter to the first hybrid and an electrical section from the third filter to the first hybrid is referred to as a second part. At least one of the first part or the second part does not include a matching network containing an inductor including a conductor of a multilayer substrate.

### TECHNICAL FIELD

The present disclosure relates to a composite filter including two or more filters and a communication device including the composite filter.

### BACKGROUND OF INVENTION

A known composite filter includes two or more filters and a 90° hybrid coupler (hereafter may be simply referred to as “hybrid”) connected to the two or more the filters (for example, Patent Literature 1 listed below). The composite filter disclosed in Patent Literature 1 is configured as a duplexer. This duplexer includes an antenna, a transmission filter, a first reception filter, and a second reception filter respectively connected to four ports of the hybrid. In Patent Literature 1, use of the hybrid enables the isolation between the transmission side and the reception side to be improved.

Generally, a matching network for realizing impedance matching is provided between each port of the hybrid and the electronic element connected to that port (a filter in Patent Literature 1). Patent Literature 1 does not mention whether or not matching networks are used.

### CITATION LIST

### Patent Literature

Patent Literature 1: International Publication No. 2009/078095

### SUMMARY

In an embodiment of the present disclosure, a composite filter includes a first hybrid, a first filter, a second filter, and a third filter. The first hybrid includes a 90° hybrid coupler including a first port and a second port, and a third port and a fourth port to which a signal input to the first or second port is distributed. The first filter is connected to the second port and has a first passband. The second filter is connected to the third port and has a second passband that does not overlap the first passband. The third filter is connected to the fourth port and has the second passband. A first part is an electrical section from the first filter to the first hybrid. A second part is a combination of an electrical section from the second filter to the first hybrid and an electrical section from the third filter to the first hybrid. At this time, at least one of the first part or the second part does not include a matching network containing an inductor including a conductor of a multilayer substrate.

In an embodiment of the present disclosure, a composite filter includes a first hybrid, a first filter, a second filter, and a third filter. The first hybrid includes a 90° hybrid coupler including a first port and a second port, and a third port and a fourth port to which a signal input to the first or second port is distributed. The first filter is connected to the second port and has a first passband. The second filter is connected to the third port and has a second passband that does not overlap the first passband. The third filter is connected to the fourth port and has the second passband. A first part is an electrical section from the first filter to the first hybrid. A second part is a combination of an electrical section from the second filter to the first hybrid and an electrical section from the third filter to the first hybrid. At this time, at least one of the first part or the second part includes a matching network containing a capacitor.

In an embodiment of the present disclosure, a communication device includes any one of the above-described composite filters, an antenna, and an integrated circuit element. The antenna is connected to the first port. The integrated circuit element is electrically connected to an opposite side of each of the first filter, the second filter, and the third filter from the first hybrid.

### BRIEF DESCRIPTION OF THE DRAWINGS

FIG. 1 is a circuit diagram illustrating the configuration of a composite filter according to a First Embodiment.

FIG. 2 is a diagram illustrating an example of the reflection characteristics of a reception filter of a composite filter according to an Example.

FIG. 3 is a diagram illustrating pass characteristics of composite filters according to a Comparative Example and an Example.

FIG. 4 is a circuit diagram illustrating the configuration of a composite filter according to a Second Embodiment.

FIG. 5 is a circuit diagram illustrating the configuration of a composite filter according to a Third Embodiment.

FIG. 6 is a schematic sectional view illustrating an example of the structure of a composite filter.

FIG. 7 is a plan view schematically illustrating the configuration of a resonator of a composite filter.

FIG. 8 is a circuit diagram schematically illustrating an example of the configurations of a transmission filter and a reception filter of a composite filter.

FIG. 9 is a block diagram illustrating an example of the configuration of a communication device including a composite filter.

### DESCRIPTION OF EMBODIMENTS

Hereafter, embodiments according to the present disclosure will be described in detail while referring to the drawings. The drawings used in the following description are schematic drawings. Therefore, for example, the dimensional ratios and so on in the drawings do not necessarily match the actual dimensional ratios and so on. The dimensional ratios and so on might not be consistent from drawing to drawing. Certain shapes and/or dimensions etc. may be exaggerated, or details may be omitted. However, this does not deny the possibility that the actual shapes and/or dimensions may be as illustrated in the drawings, or that the shapes and/or dimensions may be extracted from the drawings.

In describing multiple aspects, aspects described relatively later will essentially be described only with respect to their differences from the previously described aspects. Matters not specifically mentioned may be assumed to be the same as or similar to those in previously described aspects or may be inferred from the previously described aspects. Components corresponding to each other in multiple aspects may be denoted by the same symbols even if there are differences for the sake of convenience. Conversely, even if the components are the same, different reference numerals may be used for the convenience of explanation.

In the present disclosure, when the phase of a signal is said to be “shifted” etc., the phase may be advanced or delayed. However, for convenience, when the above kind of language is used, unless contradictions arise, “shift” etc. is assumed to mean only advanced or delayed commonly for various components and various signals etc. For example, when we say that the phase of a second signal is shifted by 90° relative to the phase of a first signal, and the phase of a fourth signal is shifted by 90° relative to the phase of a third signal, the shift in the former case and the shift in the latter case are both shifts where the phase is advanced by 90° or both shifts where the phase is delayed by 90°.

### OVERVIEW OF EMBODIMENTS

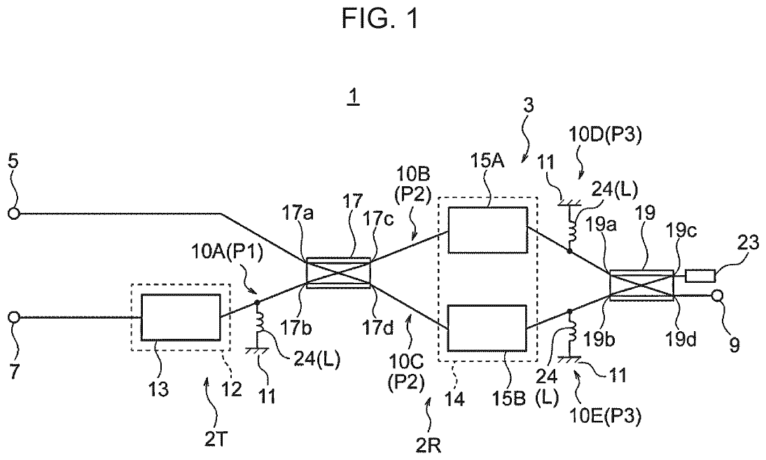

FIG. 1 is a circuit diagram illustrating the configuration of a composite filter 1 according to a First Embodiment.

The composite filter 1 is configured as a duplexer. For example, the composite filter 1 includes a transmission path 2T that filters a transmission signal from a transmission terminal 7 and outputs the filtered transmission signal to an antenna terminal 5, and a reception path 2R that filters a reception signal from the antenna terminal 5 and outputs the filtered reception signal to a reception terminal 9.

The transmission path 2T includes a transmission filter system 12 that is directly responsible for filtering of transmission signals. The transmission filter system 12 includes a transmission filter 13. The reception path 2R includes a reception filter system 14 that is directly responsible for filtering of reception signals. The reception filter system 14 includes reception filters 15A and 15B (hereafter, the two filters may be simply referred to as reception filters 15 with distinguishing therebetween).

The transmission filter system 12 (transmission filter 13) allows signals of a transmission band to pass therethrough (attenuates signals outside the transmission band). The reception filter system 14 (reception filters 15) allows signals of a reception band to pass therethrough (attenuates signals outside the reception band). The transmission band and the reception band are different frequency bands (they do not overlap each other). In other words, the transmission filter 13 and the reception filters 15 have passbands that do not overlap each other. The part of the composite filter 1 that includes the transmission filter 13 and the reception filters 15 and directly contributes to filtering is sometimes referred to as a splitter body 3.

A first hybrid 17, consisting of a 90° hybrid coupler, is inserted between the antenna terminal 5, the transmission filter 13, and the reception filters 15A and 15B. The first hybrid 17, for example, contributes to reducing nonlinear distortion (distortion signal), as described later.

The first hybrid 17 includes four ports 17a to 17d. The relationship between the ports 17a to 17d can be simply described, assuming a basic technical knowledge, as a relationship in which a signal input to the port 17a or 17b is distributed to the ports 17c and 17d. The antenna terminal 5 and the transmission filter 13 are respectively connected to the ports 17a and 17b, and the reception filters 15A and 15B are respectively connected to the ports 17c and 17d.

When a transmission signal is input to the transmission terminal 7 from outside the composite filter 1, the transmission signal is filtered by the transmission filter 13 and input to the first hybrid 17. The transmission signal input to the first hybrid 17 is divided into two transmission signals with a phase difference of 90° therebetween, and the two transmission signals are distributed to the two reception filters 15. Because the transmission band and reception band do not overlap, the two distributed transmission signals are reflected by the two reception filters 15 and input once again to the first hybrid 17. The two input transmission signals are made to be in-phase with each other and combined with each other by the first hybrid 17, and then the resulting transmission signal is output to the antenna terminal 5.

An electrical section from the transmission filter 13 to the first hybrid 17 (first section 10A) will be referred to as a first part P1. The combination of an electrical section from the reception filter 15A to the first hybrid 17 (second section 10B) and an electrical section from the reception filter 15B to the first hybrid 17 (third section 10C) will be referred to as a second part P2. The reason the term “electrical” is used here is because the “spatial” positional relationship is arbitrary. However, for convenience, such disclaimers/remarks may be omitted. As can be understood from the description of the transmission signal in the preceding paragraphs, the first part P1 and the second part P2 are included in the transmission path 2T for outputting a transmission signal input to the transmission terminal 7 to the antenna terminal 5.

At least one of the first part P1 or the second part P2 does not include a matching network containing an inductor constituted by a conductor of a multilayer substrate. For example, specific examples are given below.

For example, the composite filter 1 does not include any parts that include a multilayer substrate. Alternatively, although the composite filter 1 includes a part including a multilayer substrate, the multilayer substrate does not include built-in inductors located in the first part P1 and/or the second part P2. From another perspective (regardless of whether or not the composite filter 1 includes a multilayer substrate), for example, the first part P1 and/or the second part P2 does not include any matching network at all (example in FIG. 1) or includes a matching network that does not contain an inductor. Alternatively, the first part P1 and/or the second part P2 includes a matching network that contains an inductor, but the inductor is not built into a multilayer substrate. Examples of inductors that are not built into multilayer substrates include a chip inductor mounted on the surface of a multilayer substrate and a chip inductor embedded inside a multilayer substrate.

In the following description, electronic elements (for example, inductors) that include conductors of a multilayer substrate are sometimes referred to as “built-in” electronic elements. Electronic elements mounted on the surface of a multilayer substrate are sometimes referred to as “mounted” electronic elements. Chip-type electronic elements embedded inside multilayer substrates are sometimes referred to as “embedded” electronic elements. The word “incorporated” is sometimes used as a broader term (the antonym of “mounted”) than “built in” or “embedded”. The term “incorporated” does not require that the component be hidden inside a multilayer substrate. For example, a built-in electronic element may be partially or entirely composed of a conductor layer provided on the surface of a multilayer substrate.

Generally, matching networks, for impedance matching, are provided between a hybrid and another electronic element (here, a filter) (for example, in the first part P1 and the second part P2). However, as mentioned above, the pass characteristics of the transmission path 2T can be improved by not providing a built-in inductor in the first part P1 and/or the second part P2. More specifically, insertion loss can be reduced. One reason for this is that, for example, built-in inductors generally have a low Q-value (quality factor), and this can cause insertion loss.

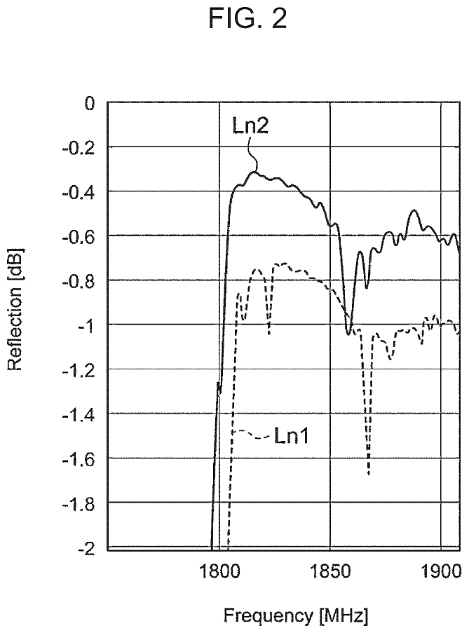

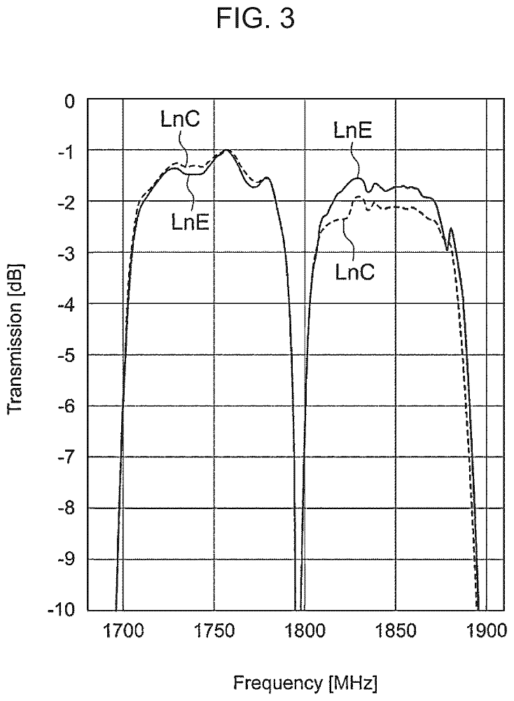

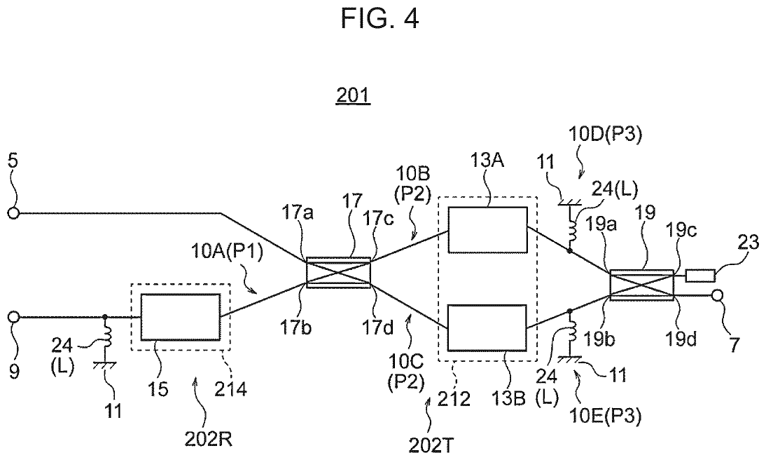

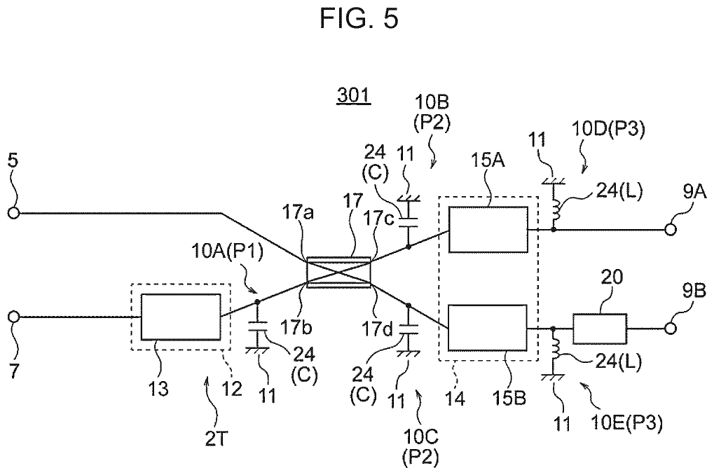

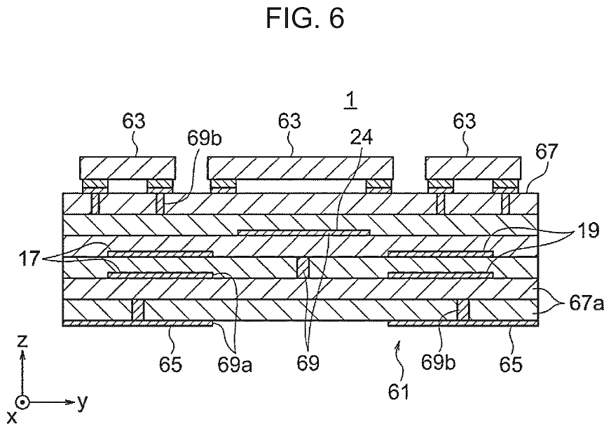

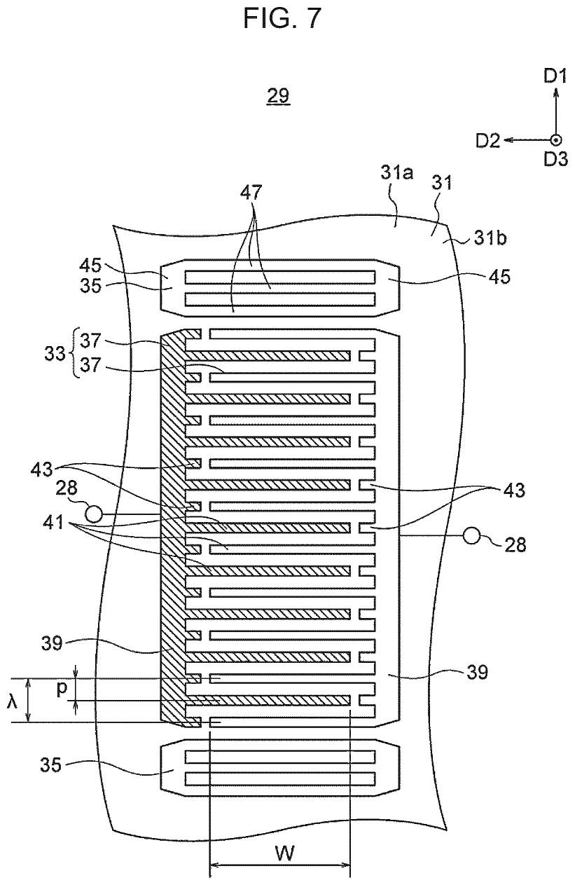

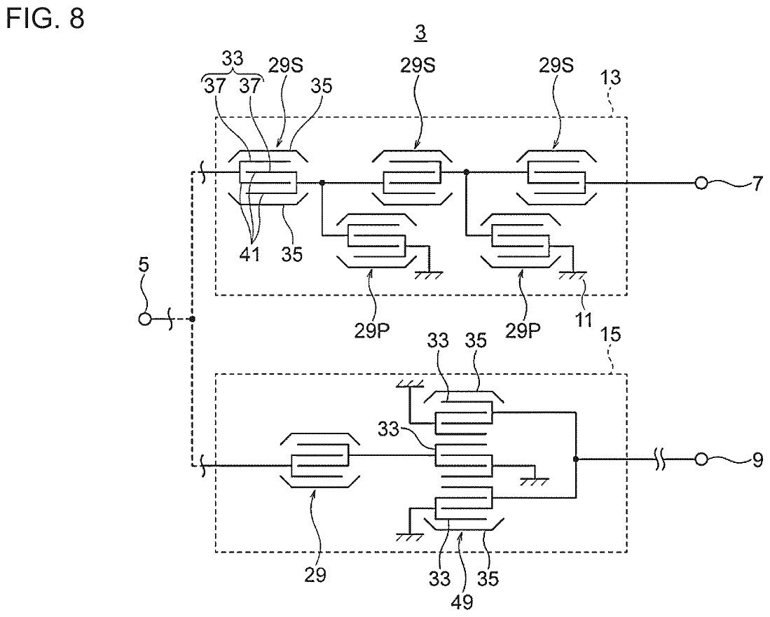

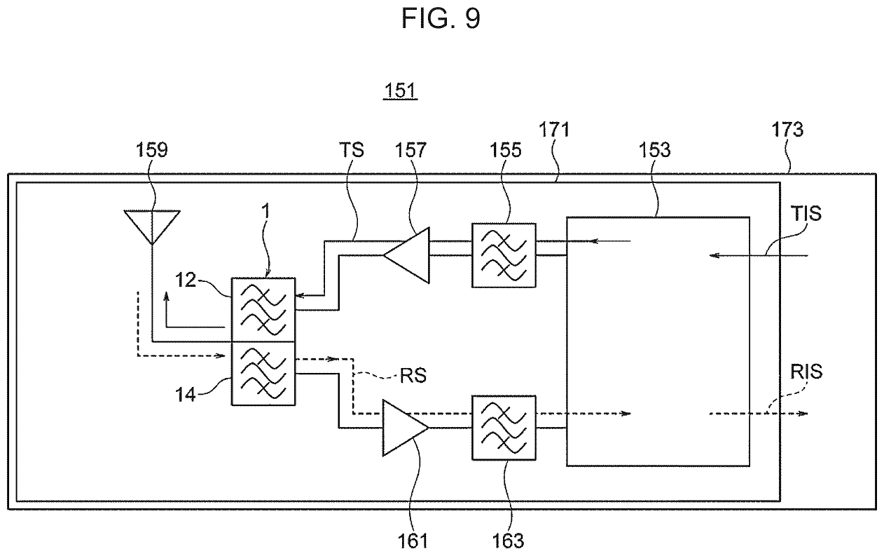

An overview of the First Embodiment has been described above. Although the First Embodiment and other embodiments differ in terms of their overall configurations, common features thereof are that the embodiments include the first hybrid 17 and three filters (13 and 15) connected to the first hybrid 17 and that the first part P1 and/or the second part P2 do not include a built-in inductor. An overview is provided hereafter and various embodiments of the present disclosure are described in the following order.
1. First Embodiment
1.1. Configuration of Composite Filter 1 (FIG. 1)
1.1.1. Filters
1.1.2. Hybrids
1.1.3. Termination Resistor
1.1.4. Matching Networks
1.2. Operation of Composite Filter 1
1.2.1. Transmission of Transmission Signal
1.2.2. Transmission of Reception Signal
1.2.3. Example of Reduction of Nonlinear Distortion
1.3. Characteristics of Comparative Example and Example (FIGS. 2 and 3)
2. Second Embodiment (FIG. 4)
3. Third Embodiment (FIG. 5)
4. Other Embodiments
5. Example Structure of Composite Filter 1 (FIG. 6)
6. Example Configurations of Transmission Filter 13 and Reception Filters 15
6.1. Example of Acoustic Wave Element (FIG. 7)
6.2. Example Configuration of Splitter Body Using Acoustic Wave Filter (FIG. 8)
7. Example of Communication Device Including Composite Filter 1 (FIG. 9)
8. Summary of Embodiments

In section 5 and subsequent sections, among multiple embodiments, the symbols for a specific embodiment (mainly the First Embodiment) may be used. However, unless there are any contradictions, the descriptions in section 5 and subsequent sections may be applied to embodiments other than the specific embodiment.

### 1. First Embodiment

### (1.1. Configuration of Composite Filter 1)

An overview of the configuration of the composite filter 1 according to the First Embodiment has already been described. In addition to the components already described above, the composite filter 1 further includes a second hybrid 19. The second hybrid 19 is inserted between the reception terminal 9 and the reception filters 15A and 15B. In addition, the composite filter 1 may include a termination resistor 23 connected to an unused port 19c of the second hybrid 19 and matching networks 24 provided at one or more suitable locations.

In the description of the overview of the embodiments, the first to third sections 10A to 10C and the first part P1 and second part P2 were defined. Similarly, the combination of an electrical section from the reception filter 15A to the second hybrid 19 (fourth section 10D) and an electrical section from the reception filter 15B to the second hybrid 19 (fifth section 10E) will be referred to as a third part P3.

Each of the first to fifth sections 10A to 10E is interposed between one filter (13 or 15) and one hybrid (17 or 15). Each section refers to the entire region between the one filter and the one hybrid not including the one filter and the one hybrid. Therefore, for example, when the second section 10B is said to not include a matching network, there is no matching network between the reception filter 15A and the first hybrid 17. In other words, when the second section 10B is said to not include a matching network, this is not intended to imply that there is another section provided in series with the second section 10B between the reception filter 15A and the first hybrid 17 and that this other section could include a matching network. This also applies to the first to third parts P1 to P3.

In addition, each of the first to fifth sections 10A to 10E is regarded as a broad concept that includes not only the components (components connected in series) that connect the one filter and one hybrid to each other, but also components that are connected in other ways between the one filter and the one hybrid. For example, not only the wiring line connecting the one filter and one hybrid to each other, but also an electronic element (e.g., an inductor) connecting the wiring line and a reference potential portion 11 to each other are included in the section between the one filter and the one hybrid. Therefore, for example, if the electronic element is included in a matching network, the section is considered to include the matching network. This also applies to the first to third parts P1 to P3.

The reference potential portion 11 is a portion (conductor) to which a reference potential is applied. More specifically, for example, this portion could be a terminal to which a reference potential is applied or could be a component other than a terminal (e.g., shielding).

Hereafter, the components of the composite filter 1 will be described in order.

### (1.1.1. Filters)

The transmission filter 13 is a band pass filter having a prescribed transmission band as the passband thereof. Similarly, the reception filters 15 are band pass filters having a prescribed reception band as the passband thereof. The transmission band and the reception band may conform to various standards, for example. In addition, the transmission band may include two or more transmission bands that conform to prescribed standards. This also applies to the reception band.

The reception filters 15A and 15B correspond to the same reception band. In other words, the reception filters 15A and 15B have the same passband in practice and/or by design. The reception filters 15A and 15B have the same or similar configurations, and have identical characteristics in practice or by design. However, the reception filters 15A and 15B may be fine-tuned so that the passbands are slightly different and/or so that the characteristics are slightly different.

The specific configurations of the transmission filter 13 and the reception filters 15 may be, for example, a known configuration or a configuration obtained by applying a known configuration. For example, the transmission filter 13 and/or the reception filters 15 may be piezoelectric filters that include a piezoelectric body, dielectric filters that utilize electromagnetic waves inside a dielectric, LC filters that use a combination of inductors and capacitors, or a combination of two or more of these types of filters. Piezoelectric filters may, for example, may utilize acoustic waves, or not utilize acoustic waves (for example, may utilize piezoelectric transducers). Acoustic waves include, for example, SAW (surface acoustic waves), BAW (bulk acoustic waves), elastic boundary waves, plate waves, and bulk waves (however, these acoustic waves are not necessarily distinguishable from each other). The plate waves and bulk waves may propagate in a direction in which the plate (piezoelectric body) expands, or may propagate in the thickness direction of the plate.

### (1.1.2. Hybrids)

The first hybrid 17 includes the four ports 17a to 17d that are used for input and/or output of signals, and in addition, functions as a distributor, a synthesizer, and a 90° phase shifter. The configuration of the first hybrid 17 may be, for example, a known configuration or a configuration obtained by applying a known configuration. For example, although not specifically illustrated, the first hybrid 17 may have a distributed constant configuration or a lumped constant configuration. A branch line coupler is a well known example of the first hybrid 17.

Each of the ports 17a and 17b on the left side of the drawing is conductive with each of the ports 17c and 17d on the right side of the drawing. “Conductive with” here means that a signal can be made to flow. Therefore, for example, a signal input to the port 17a can be output from the ports 17c and 17d.

For convenience, in the description of this embodiment, the description may be made based on the relative positions of the ports 17a to 17d in the diagram illustrating the first hybrid 17. However, the relative positions of the four ports 17a to 17d in the diagram do not necessarily need to match the actual relative positions of the four ports 17a to 17d.

A signal input to the port 17a on the left side of the drawing is distributed to the ports 17c and 17d on the right side of the drawing. The distribution ratio at this time (the ratio of the intensities of the two distributed signals) is 1:1. The intensity is, for example, voltage, current and/or power. The two distributed signals are 90 degrees out of phase with each other.

The phase of the signal before distribution (for example, the signal input to the port 17a) may be the same as the phase of one of the two signals after distribution (for example, the signal output from the port 17c). In addition, unlike the above example, the phase of the signal before distribution and the phases of the two signals after distribution may be different from each other. However, for the sake of convenience, in the description of this embodiment, we may sometimes assume that the phase of the signal before distribution is the same as the phase of one of the two signals after distribution. More specifically, the description may be given as though signals at ports at the same position in the vertical direction in the drawing (e.g., the ports 17a and 17c) have the same phase.

Although a case in which a signal is input to the port 17a has been described as an example, an operation the same as or similar to that described above is performed when signals are input to the other ports 17b to 17d. In other words, a signal input to one of the two ports located on one side of the drawing in the left-right direction is distributed with a 1:1 distribution ratio and output from the two ports located on the other side of the drawing in the left-right direction. At this time, the two distributed signals are 90 degrees out of phase with each other.

As described above, when a phase shift is mentioned, for convenience, this refers to the phase either being advanced or delayed commonly for various components and various signals. In the drawings, the phase of a signal output from a port (e.g., 17d) located at a different position in the vertical direction in the drawing from a port to which a signal was input (e.g., 17a) is assumed to be shifted by 90° with respect to the phase of a signal output from a port (e.g., 17c) located at the same position in the vertical direction in the drawing as the port to which the signal was input.

Since a circuit operating as described above is called a 90° hybrid, the relationship between the four ports of the first hybrid 17 can be identified from the description of only some of the ports. For example, let us suppose that the port 17d is described as a port to which a signal is distributed from the port 17a with a phase that is shifted by 90° with respect to the phase of a signal distributed from the port 17a to the port 17c. From this description, we can deduce that the port 17a and the remaining port 17b are located on the same side of the drawing in the left-right direction and the port 17c and the port 17d are located on the opposite side of the drawing in the left-right direction, and that the port 17a and the port 17c are located on the same side of the drawing in the vertical direction and the port 17b and port 17d are located on the opposite side of the drawing in the vertical direction. When the relationship between the four ports is described using a signal distributed from the port 17a as described above, the first hybrid 17 does not need to be provided in such a manner that the signal is actually input from the port 17a. This also applies to cases described with distribution from other ports.

For example, when there is no particular need to distinguish between two ports that are positioned on the same side of the drawing in the left-right direction (for example, the ports 17c and 17d), a more concise description can be given. For example, as mentioned in the description of the overview of the embodiment, in the description, the ports 17c and 17d are assumed to be ports to which a signal input to the port 17a or 17b is distributed. From this description, we can deduce that the port 17a and the remaining port 17b are positioned on the same side of the drawing in the left-right direction, and that the ports 17c and 17d are positioned on the opposite side of the drawing in the left-right direction. When the relationship between the four ports is described using a signal distributed from the port 17a or 17b as described above, the first hybrid 17 does not need to be provided in such a manner that the signal is actually input from the port 17a or 17b. This also applies to cases described with distribution from other ports.

When signals are input to the ports 17a and 17b on the left side of the drawing, the signals are distributed as described above, and then the distributed signals are combined. For example, let us regard a signal input to the port 17a as a first signal, and a signal input to the port 17b as a second signal. Signals resulting from the first signal being distributed to the ports 17c and 17d are a third signal and a fourth signal. The fourth signal is 90 degrees out of phase with the third signal. Signals resulting from the second signal being distributed to the ports 17c and 17d are a fifth signal and a sixth signal. The fifth signal is 90 degrees out of phase with the sixth signal. At this time, a signal formed by combining the third signal and the fifth signal is output to the port 17c, and a signal formed by combining the fourth signal and the sixth signal is output to the port 17d. A case where signals are input to the two ports 17a and 17b on the left side of the drawing is described as an example, but the same or similar applies to a case where signals are input to the two ports 17c and 17d on the right side of the drawing.

As mentioned above, for example, there may be a phase difference between the first signal (input to the port 17a) and the third signal (distributed to the port 17c without being phase shifted), and there may be a phase difference between the second signal (input to the port 17b) and the sixth signal (distributed to the port 17d without being phase shifted). In this case, the two phase differences are identical. The two phase differences when the signals are in opposite directions are identical to the two phase differences described above.

Although the first hybrid 17 has been described, the above description may be applied to the second hybrid 19 by substituting the term second hybrid 19 for the term first hybrid 17 and substituting the terms ports 19a to 19d for the terms ports 17a to 17d. The specific configuration (for example, the shape and dimensions of the conductors) of the first hybrid 17 and the specific configuration of the second hybrid 19 may be the same as or different from each other.

In the first hybrid 17, the connection relationships between the ports 17a to 17d and the other elements (the antenna terminal 5, the transmission filter 13 and the two reception filters 15) have already been described. In the second hybrid 19, the port 19a is connected to the reception filter 15A. The port 19b is connected to the reception filter 15B. The port 19c is connected to the termination resistor 23 as previously mentioned. The port 19d is connected to the reception terminal 9.

### (1.1.3. Termination Resistor)

The termination resistor 23, for example, has a prescribed resistance value and connects the port 19c of the second hybrid 19 to a reference potential portion (not illustrated). This reduces the reflection of signals flowing from the port 19a and/or 19b to the port 19c, for example. The resistance value of the termination resistor 23 may be set as appropriate in accordance with the impedance on the second hybrid 19 side from the termination resistor 23, but is generally 50 ohms.

The configuration of the termination resistor 23 may be, for example, a known configuration or a configuration obtained by applying a known configuration. For example, although not specifically illustrated, the termination resistor 23 may be a mounted, embedded or built-in resistor positioned on or in a circuit board (e.g., a multilayer substrate 61 described below). In addition, the termination resistor 23 may be a built-in resistor (for example, a conductor pattern that overlaps a top surface 31a of a piezoelectric body 31b, which will be described later) positioned in a piezoelectric property substrate 31, which will be described later. In addition, the termination resistor 23 may be provided outside the composite filter 1.

### (1.1.4. Matching Networks)

The matching network 24 is for improving impedance matching and may be provided at any position and with any configuration. However, as mentioned above, at least one of the first part P1 or the second part P2 does not include the matching network 24 containing a built-in inductor.

In the example in FIG. 1, the second part P2 does not include the matching network 24 itself. For example, the second part P2 does not include any built-in inductor, but also any other type of inductor, and also does not include various types of capacitors or various types of resistors. In other words, only a wiring line is connected between the port 17c and the reception filter 15A, and only a wiring line is connected between the port 17d and the reception filter 15B.

In addition, when each part (P1 to P3) or each section (10A to 10E) is said to not include a matching network, the part or section may not include any electronic elements at all (inductors, capacitors, resistors, etc.) or may include electronic components that do not constitute a matching network. In addition, regarding the presence or absence of a matching network, the resistance, capacitance and inductance that are inevitably included in the wiring line itself are ignored.

In the example in FIG. 1, the composite filter 1 includes the matching network 24 in positions other than the second part P2. More specifically, the matching network 24 is provided in three locations, namely, in the first section 10A, the fourth section 10D, and the fifth section 10E. However, these positions are merely examples of where the matching network 24 is provided. For example, the matching network 24 may be provided at positions other than the above three positions, or may not be provided at any of the above three positions. In addition, the matching network 24 does not need to be provided at all.

In FIG. 1, each matching network 24 is illustrated as being configured by an inductor L that connects the path along which a signal flows and the reference potential portion 11. However, this is merely an example. For example, the component that makes up the matching network 24 may be a capacitor or a resistor. The matching network 24 may be a combination of two or more components. Each of the one or more components constituting the matching network 24 may connect a path along which a signal flows to the reference potential portion 11, or may be connected in series to the path along which the signal flows.

In FIG. 1, the three matching networks 24 (inductors L) are denoted by the same symbol, but may of course have different configurations. In addition, each of the one or more components that constitute each matching network 24 may be of any of built-in, mounted, or embedded components.

The matching network 24 of the first section 10A, for example, may contribute to making the impedance seen from the port 17b of the first hybrid 17 when looking toward the transmission filter 13 equal to a reference value (for example, 50Ω or less, the same applies hereafter). In addition to or instead of this kind of impedance matching, the matching network 24 of the first section 10A may contribute to making the impedance seen from the transmission terminal 7 when looking toward the transmission filter 13 equal to a reference value.

The matching network 24 of the fourth section 10D, for example, contributes to making the impedance seen from the port 19a of the second hybrid 19 when looking toward the reception filter 15A equal to a reference value. In addition to or instead of this kind of impedance matching, the matching network 24 of the fourth section 10D may contribute to making the impedance seen from the port 17c of the first hybrid 17 when looking toward the reception filter 15A equal to a reference value.

The matching network 24 of the fifth section 10E, for example, contributes to making the impedance seen from the port 19b of the second hybrid 19 when looking toward the reception filter 15B equal to a reference value. In addition to or instead of this kind of impedance matching, the matching network 24 of the fifth section 10E may contribute to making the impedance seen from the port 17d of the first hybrid 17 when looking toward the reception filter 15B equal to a reference value.

The fact that a specific matching network 24 contributes to impedance matching seen from a specific position can be determined by, for example, observing that the impedance seen from the specific position is closer to the reference value when the specific matching network 24 is provided than when the specific matching network 24 is not provided. For example, if the impedance seen from the port 17c of the first hybrid 17 when looking toward the reception filter 15A is closer to the reference value (ideally, matches the reference value) when the matching network 24 of the fourth section 10D is provided than when the matching network 24 is not provided, the matching network 24 can be considered to contribute to impedance matching when looking from the port 17c toward the reception filter 15A. The reference value may be specified from the specifications of the composite filter 1, etc., or may be specified by measuring the impedance seen from various positions.

### (1.2. Operation of Composite Filter)

### (1.2.1. Transmission of Transmission Signal)

A general outline of the operation of transmitting a signal (transmission signal) input to the transmission terminal 7 from outside the composite filter 1 to the antenna terminal 5 has already been described. This will be described in more detail below.

The signal is filtered by the transmission filter 13 and a signal with a frequency in the passband of the transmission filter 13 is input to the port 17b of the first hybrid 17. The signal input to the port 17b is distributed to the port 17c and the port 17d. The phase of the signal distributed to the port 17c is shifted by 90° with respect to the phase of the signal distributed to the port 17d.

The signal distributed to the port 17c and output from the port 17c is a signal with a frequency in the passband (transmission band) of the transmission filter 13, and therefore is reflected by the reception filter 15A without passing through the reception filter 15A, which has a passband (reception band) different from the transmission band. Therefore, the signal output from the port 17c is returned to the port 17c. Similarly, the signal distributed to the port 17d and output from the port 17d is reflected by the reception filter 15B and returned to the port 17d.

The signal returned to the port 17c is distributed to the ports 17a and 17b. At this time, the phase of the signal distributed to the port 17b is shifted by 90° relative to the phase of the signal distributed to the port 17a. Similarly, the signal returned to the port 17d is distributed to the ports 17a and 17b. At this time, the phase of the signal distributed to the port 17a is shifted by 90° relative to the phase of the signal distributed to the port 17b.

The signal that passed through the transmission filter 13, the ports 17b and 17c in that order, was reflected by the reception filter 15A, returned to the port 17c, and transmitted to the port 17a, and the signal that passed through the transmission filter 13, the ports 17b and 17d in that order, was reflected by the reception filter 15B, returned to the port 17d, and transmitted to the port 17a are in phase with each other because these signals have both undergone a 90° phase shift one time. Therefore, the two signals are combined with each other and output to the antenna terminal 5 from the port 17a.

On the other hand, the signal that was transmitted through the ports 17b and 17d in that order from the transmission filter 13, reflected by the reception filter 15B, returned to the port 17d, and transmitted to the port 17b does not undergo a 90° phase shift. In addition, the signal that was transmitted through the ports 17b and 17c in that order from the transmission filter 13, reflected by the reception filter 15A, returned to the port 17c, and transmitted to the port 17b undergoes a 90° phase shift twice. Therefore, the two signals have opposite phases and cancel each other out, and are not output from the port 17b.

For the sake of explanation, the signal returning to the port 17c or 17d was described as being distributed to the port 17b, but the fact that no signal is output from the port 17b means that no signal is actually distributed to the port 17b. In other words, if we ignore insertion loss, the intensity of the signal output to the antenna terminal 5 is the same as the intensity of the signal input to the transmission terminal 7.

When we focus on only the first hybrid 17, the port 17b to which the transmission filter 13 is connected and the port 17a to which the antenna terminal 5 is connected are not conductive with each other. As described above, the signal from the transmission filter 13 is transmitted to the antenna terminal 5 by utilizing reflection at the reception filters 15. In this case as well, the transmission filter 13 is described as being connected to the antenna terminal 5 via the first hybrid 17.

### (1.2.2. Transmission of Reception Signal)

A signal input to the port 17a of the first hybrid 17 from the antenna terminal 5 (reception signal) is distributed to the ports 17c and 17d. The phase of the signal distributed to the port 17d is shifted by 90° relative to the phase of the signal distributed to the port 17c.

The signal distributed to the port 17c and output from the port 17c is input to the port 19a of the second hybrid 19 via the reception filter 15A. The signal distributed to the port 17d and output from the port 17d is input to the port 19b of the second hybrid 19 via the reception filter 15B.

The signal input to the port 19a is distributed to the ports 19c and 19d. The phase of the signal distributed to the port 19d is shifted by 90° relative to the phase of the signal distributed to the port 19c. Similarly, the signal input to the port 19b is distributed to the ports 19c and 19d. At this time, the phase of the signal distributed to the port 19c is shifted by 90° relative to the phase of the signal distributed to the port 19d.

The signal transmitted from antenna terminal 5 to the port 19d via the ports 17a and 17c, the reception filter 15A, and the port 19a in that order, and the signal transmitted from the antenna terminal 5 to the port 19d via the ports 17a and 17d, the reception filter 15B, and the port 19b in that order both undergo a 90° shift one time and are therefore in phase with each other. Therefore, the two signals are combined with each other and output to the reception terminal 9 from the port 19d.

On the other hand, the signal transmitted from the antenna terminal 5 to the port 19c via the ports 17a and 17c, the reception filter 15A, and the port 19a in that order does not undergo a 90° phase shift. In addition, the signal transmitted from the antenna terminal 5 to the port 19c via the ports 17a and 17d, the reception filter 15B, and the port 19b in that order undergoes a 90° phase shift twice. Therefore, the two signals have opposite phases and cancel each other out, and are not output from the port 19c.

For the sake of explanation, the signal input to the port 19a or 19b was described as being distributed to the port 19c, but the fact that no signal is output from the port 19c means that no signal is actually distributed to the port 19c. In other words, if we ignore insertion loss, the intensity of the signal output to the reception terminal 9 is the same as the intensity of the signal input to the antenna terminal 5.

### (1.2.3. Example of Reduction of Nonlinear Distortion)

In the transmission filter 13 and/or the reception filter 15, nonlinear distortion (distortion signal) such as intermodulation distortion may occur due to the non-linearity of the filters. An example of the way in which nonlinear distortion is reduced by using a hybrid will be described.

Let us assume that two signals are input to the transmission terminal 7, and nonlinear distortion occurs in the transmission filter 13. This nonlinear distortion is assumed to have a frequency within the reception band of the reception filters 15 and is able to pass through the reception filters 15.

The nonlinear distortion input to the port 17b from the transmission filter 13 is distributed to the ports 17c and 17d. The phase of the nonlinear distortion distributed to the port 17c is shifted by 90° relative to the phase of the nonlinear distortion distributed to the port 17d.

The nonlinear distortion distributed to the port 17c and output from the port 17c is input to the port 19a of the second hybrid 19 via the reception filter 15A. The nonlinear distortion distributed to the port 17d and output from the port 17d is input to the port 19b of the second hybrid 19 via the reception filter 15B.

The nonlinear distortion input to the port 19a is distributed to the ports 19c and 19d. At this time, the phase of the nonlinear distortion distributed to the port 19d is shifted by 90° relative to the phase of the nonlinear distortion distributed to the port 19c. Similarly, the nonlinear distortion input to the port 19b is distributed to the ports 19c and 19d. The phase of the nonlinear distortion distributed to the port 19c is shifted by 90° relative to the phase of the nonlinear distortion distributed to the port 19d.

The nonlinear distortion transmitted from the transmission filter 13 to the port 19d via the ports 17b and 17c, the reception filter 15A, and the port 19a in that order undergoes a 90° phase shift twice. In addition, the nonlinear distortion transmitted from the transmission filter 13 to the port 19d via the ports 17b and 17d, the reception filter 15B, and the port 19b in that order does not undergo a 90° phase shift. Therefore, the two nonlinear distortion signals have opposite phases and cancel each other out, and are not output from the port 19d. In other words, the nonlinear distortion is not input to the reception terminal 9.

On the other hand, the nonlinear distortion transmitted from transmission filter 13 to the port 19c via the ports 17b and 17c, the reception filter 15A, and the port 19a in that order, and the nonlinear distortion transmitted from the transmission filter 13 to the port 19c via the ports 17b and 17d, the reception filter 15B, and the port 19b in that order both undergo a 90° shift one time and are therefore in phase with each other. Therefore, the two signals are combined with each other and input to the termination resistor 23 from the port 19c. Furthermore, the nonlinear distortion is released to the reference potential portion etc. via the termination resistor 23.

Next, let us assume that nonlinear distortion occurs in the reception filters 15 when a transmission signal that is input to the transmission terminal 7 from the outside and passes through the transmission filter 13 and the first hybrid 17 is reflected in the reception filters 15. The phase relationship of the nonlinear distortion generated in the reception filter 15A and the reception filter 15B is the same as or similar to the phase relationship of the nonlinear distortion generated in the transmission filter 13 described above and propagated to the reception filters 15A and 15B. Therefore, the nonlinear distortion is absorbed by the termination resistor 23 based on principles the same as or similar to those described above (nonlinear distortion is not input to the reception terminal 9).

### (1.3. Characteristics of Comparative Examples and Examples)

FIG. 2 is a diagram illustrating the reflection characteristics of the second section 10B and the reception filter 15A in a Comparative Example. This diagram is obtained by measuring the characteristics of test pieces.

In the Comparative Example, although not specifically illustrated, the second section 10B includes the matching network 24. This matching network 24 includes (only) an inductor. One end of the inductor is connected between the port 17c of the first hybrid 17 and the reception filter 15A, and the other end of the inductor is connected to the reference potential portion 11. The fourth section 10D does not include a matching network. The inductor is a built-in-type inductor.

In FIG. 2, the horizontal axis represents frequency (MHz). The vertical axis represents reflection characteristics (dB). A line Ln1 represents the reflection characteristic (S11 parameter) seen from the port 17c when looking toward the reception filter 15A. A line Ln2 represents the reflection characteristic (S22 parameter) seen from the end of the reception filter 15A on the side where the second hybrid 19 is located when looking toward the reception filter 15A. The range from approximately 1700 MHz to approximately 1800 MHz corresponds to the reception band. The range from approximately 1800 MHz to approximately 1900 MHz corresponds to the transmission band.

As illustrated in this figure, the S11 parameter (line Ln1) is lower than the S22 parameter (line Ln2) in the transmission band. In other words, in the Comparative Example, the reflection characteristic seen when looking from the first hybrid 17 toward the reception filter 15A is reduced due to the fact that the second section 10B includes a matching network with a built-in inductor. On the other hand, as mentioned above, a transmission signal input to the transmission terminal 7 from outside the composite filter 1 is reflected by the reception filter 15 and output to the antenna terminal 5. Therefore, insertion loss occurs due to the decrease in the reflection characteristics as described above, and the pass characteristics of the transmission path 2T decrease.

FIG. 3 is a diagram illustrating pass characteristics of a Comparative Example and an Example. This figure is obtained by performing simulation calculations.

In the Example, similarly to as in FIG. 1, the first section 10A, the fourth section 10D, and the fifth section 10E include the matching network 24, and the second section 10B and the third section 10C do not include the matching network 24. In the Comparative Example, the first section 10A, the second section 10B, and the third section 10C include the matching network 24, and the fourth section 10D and the fifth section 10E do not include the matching network 24. Each matching network 24 includes (only) an inductor L that connects the signal path and the reference potential portion 11, similarly to the matching network 24 illustrated in FIG. 1.

In FIG. 3, the horizontal axis represents frequency (MHz). The vertical axis represents pass characteristics (dB). A line LnE represents a characteristic of the Example. A line LnC represents a characteristic of the Comparative Example. The range from approximately 1700 MHz to approximately 1800 MHz corresponds to the reception band. The range from approximately 1800 MHz to approximately 1900 MHz corresponds to the transmission band.

As illustrated in this figure, in the transmission band, the pass characteristics of the Example are improved compared to the Comparative Example. In the reception band, the pass characteristics of the Example are reduced compared to the pass characteristics of the Comparative Example. However, the extent of this reduction is small compared to the extent of the improvement in the pass characteristics in the transmission band. Thus, the pass characteristics of the entire passband of the composite filter 1 (the entire transmission band and reception band) are improved on average by not providing the matching network 24 in the second part P2 and focusing on the matching network 24 in the third part P3.

### 2. Second Embodiment

FIG. 4 is a circuit diagram illustrating the configuration of a composite filter 201 according to a Second Embodiment.

In short, the composite filter 201 has a configuration obtained by swapping the transmission filter 13 and the reception filters 15 and swapping the transmission terminal 7 and the reception terminal 9 in the composite filter 1 of the First Embodiment. In addition, an example is illustrated in which positions of the matching networks 24 are different from in the First Embodiment. For convenience of explanation, the first to fifth sections 10A to 10E and the first to third parts P1 to P3 indicate the same positions as in FIG. 1 with respect to the first hybrid 17 and the second hybrid 19.

A transmission path 202T includes the second hybrid 19, a transmission filter system 212, and the first hybrid 17, in that order, from the transmission terminal 7 to the antenna terminal 5. In contrast to the First Embodiment, the transmission filter system 212 includes two transmission filters 13 (13A and 13B). Regarding the connection relationship between these components, the description of the connection relationship for the reception path 2R in the First Embodiment may be used. However, the words reception filters 15A and 15B (15) are replaced with the words transmission filters 13A and 13B (13), and the words reception terminal 9 are replaced with the words transmission terminal 7.

The two transmission filters 13 correspond to the same passband (but a transmission band, unlike in the First Embodiment) similarly to the two reception filters 15 in the First Embodiment. For example, the two transmission filters 13 may have the same configuration and characteristics as each other, similarly to the two reception filters 15 in the First Embodiment.

A reception path 202R includes a reception filter system 214 and the first hybrid 17 in this order from the antenna terminal 5 to the reception terminal 9. In contrast to the First Embodiment, the reception filter system 214 includes one reception filter 15. Regarding the connection relationship between these components, the description of the connection relationship for the transmission path 2T in the First Embodiment may be used. However, the words transmission filters 13 are replaced with the words reception filter 15, and the words transmission terminal 7 are replaced with the words reception terminal 9.

In the thus-configured composite filter 201 as well, the intensities of the transmission signal and reception signal are maintained. On the other hand, nonlinear distortion that passes through the transmission filter 13A and nonlinear distortion that passes through the transmission filter 13B cancel each other out.

Specifically, for example, a signal (for example, a reception signal) input to the antenna terminal 5 from outside the composite filter 201 is input to the first hybrid 17, and is distributed to the two transmission filters 13 by the first hybrid 17. The two distributed signals are reflected by the two transmission filters 13 and re-input to the first hybrid 17. The two signals input to the first hybrid 17 are combined and output to the reception filter 15 (not output to the antenna terminal 5).

For example, out of signals (for example, transmission signals) input to the port 19d from the transmission terminal 7, a signal that passes through the port 19a, the transmission filter 13A, and the port 17c in that order and reaches the port 17a, and a signal that passes through the port 19b, the transmission filter 13B, and the port 17d in that order and reaches the port 17a are in-phase signal and combine with each other, and the resulting signal is output to the antenna terminal 5. Out of signals input to the port 19d from the transmission terminal 7, a signal that passes through the port 19a, the transmission filter 13A, and the port 17c in that order and reaches the port 17b, and a signal that passes through the port 19b, the transmission filter 13B, and the port 17d in that order and reaches the port 17b are signals having opposite phases from each other and are not output from the port 17b.

For example, if two signals are input to the port 19d from the transmission terminal 7 and nonlinear distortion occurs in each of the transmission filters 13A and 13B, similarly to as described in the preceding paragraphs, the signals input to the ports 17c and 17d and directed toward the port 17b have opposite phases from each other and are not output from the port 17b.

In the composite filter 201, the matching network 24 is provided in neither the second part P2 nor the first part P1. In addition, in the composite filter 201, the matching network 24 is provided in the section between the reception filter 15 and the reception terminal 9. As mentioned above, this matching network 24 can have various configurations, and in FIG. 4, an inductor L that connects the signal path and the reference potential portion 11 is illustrated as an example, similarly to as in FIG. 1.

The matching network 24 between the reception filter 15 and the reception terminal 9 contributes to making the impedance seen when looking from the reception terminal 9 (or, from another perspective, an external circuit connected to the reception terminal 9) toward the reception filter 15 equal to a reference value. In addition to or instead of this kind of impedance matching, the matching network 24 may also contribute to making the impedance seen when looking toward the reception filter 15 from the port 17b of the first hybrid 17 equal to a reference value. The matching network 24 between the reception filter 15 and the reception terminal 9 can also be provided between the reception terminal 9 and an external circuit connected to the reception terminal 9.

In the Second Embodiment as well, at least one of the first part P1 or the second part P2 (in the illustrated example, both) does not include a matching network containing a built-in inductor, and therefore insertion loss can be reduced and pass characteristics can be improved.

### 3. Third Embodiment

FIG. 5 is a circuit diagram illustrating the configuration of a composite filter 301 according to a Third Embodiment.

In short, the composite filter 301 has a configuration obtained by omitting the second hybrid 19 from the composite filter 1 of the First Embodiment and providing reception terminals 9A and 9B respectively corresponding to the reception filters 15A and 15B and providing a 90° phase shifter 20 (hereinafter simply referred to as “phase shifter 20”) between the reception filter 15B and the reception terminal 9B in the composite filter 1 of the First Embodiment. In addition, a different configuration is illustrated for the matching networks 24 from that in the First Embodiment. For convenience of explanation, the first to fifth sections 10A to 10E and the first to third parts P1 to P3 indicate the same positions as in FIG. 1 with respect to the first hybrid 17 and the reception filters 15A and 15B.

Operations relating to transmitting a transmission signal input to the transmission terminal 7 from outside the composite filter 301 are the same as or similar to those in the First Embodiment. Operations relating to the transmission of a reception signal input from outside the composite filter 301 to the antenna terminal 5 are the same as or similar to those in the First Embodiment up until the signal passes through the reception filters 15A and 15B. After that, the reception signal that passes through the reception filter 15B is phase shifted by 90° by the phase shifter 20. As a result, the phase of the reception signal that has passed through the reception filter 15B is shifted by 180°, including the phase shift caused by the first hybrid 17, with respect to the phase of the reception signal that has passed through the reception filter 15A. The two reception signals are then output from the two reception terminals 9 (9A and 9B) as balanced signals indicating a signal strength according to the potential difference therebetween.

In the composite filter 301, signals (for example, nonlinear distortion) distributed from the transmission filter 13 to the reception filters 15A and 15B by the first hybrid 17 are finally made to be in-phase signals by the phase shifter 20 and output to the reception terminals 9A and 9B. Thus, in principle, the signals from the transmission filter 13 described above do not affect the potential difference of the balanced signals described in the preceding paragraphs.

At least one of the first part P1 or the second part P2 (both in the illustrated example) does not include a matching network containing a built-in inductor, similarly to as in the First Embodiment, and furthermore, in the illustrated example, does not include a matching network containing an inductor (of any type). However, an example is illustrated here in which the first part P1 and the second part P2 each include a matching network 24 containing a capacitor C.

The matching network 24 of the first section 10A, for example, contributes to bringing the impedance seen when looking from the port 17b toward the transmission filter 13 closer to a reference value. The matching network 24 of the second section 10B, for example, contributes to bringing the impedance seen when looking from the port 17c toward the reception filter 15A closer to a reference value. The matching network 24 of the third section 10C, for example, contributes to bringing the impedance seen when looking from the port 17d toward the reception filter 15B closer to a reference value.

### 4. Other Embodiments

Although not specifically illustrated, a composite filter may have various circuit configurations other than the above-described embodiments.

For example, first, the arrangement and/or configuration of the matching networks 24 in each of the first to Third Embodiments may be applied to other embodiments (and may be combined with configurations other than the matching networks 24 in the other embodiments). Specifically, the configuration in the Second Embodiment in which the matching network 24 is provided in neither the first part P1 nor the second part P2 may be applied to the First Embodiment or the Third Embodiment. The configuration in the First Embodiment in which the matching network 24 is not provided in the second part P2 out of the first part P1 and the second part P2 (the matching network 24 is provided in the first part P1) may be applied to the Second Embodiment or the Third Embodiment. The configuration of the Third Embodiment in which at least one of the first part P1 or the second part P2 includes the matching network 24 containing the capacitor C may be applied to the First Embodiment or the Second Embodiment.

As mentioned above, at least one of the first part P1 or the second part P2 does not include the matching network 24 containing a built-in inductor L. In the description of the first to Third Embodiments, a configuration in which the second part P2 does not include the matching network 24 containing the built-in inductor L (First Embodiment) and a configuration in which both the first part P1 and the second part P2 do not include the matching network 24 containing the built-in inductor L (Second and Third Embodiments) were described as examples. Unlike these configurations, the first part P1 does not need to include the matching network 24 containing the built-in inductor L (the second part P2 may include the matching network 24 containing the built-in inductor L).

The presence or absence of the various matching networks 24 in the first part P1 and second part P2 may be freely decided upon so long as at least one of the first part P1 or the second part P2 does not include the matching network 24 containing the built-in inductor L. For example, four configurations related to the matching network 24 of the first part P1 are a configuration including a matching network 24 containing a built-in inductor L (hereinafter referred to as “configuration A”), a configuration including a matching network 24 not containing a built-in inductor L but containing an inductor L other than a built-in inductor (hereinafter referred to as “configuration B”), a configuration including a matching network 24 not containing an inductor L (regardless of type) but containing an element other than an inductor (hereinafter referred to as “configuration C”), and a configuration not including any matching network at all (hereinafter referred to as “configuration D”). This similarly applies to the second part P2. Therefore, the total number of configurations of the first part P1 and the second part P2 is 4×4=16. From these 16 configurations, any one of the 15 configurations may be used except for the one where both the first part P1 and the second part P2 are configuration A.

A number of configurations will be picked out from the above fifteen configurations. For example, the second part P2 may use configuration D and the first part P1 may use configuration A, configuration B, or configuration C. The second part P2 may use configuration C and the first part P1 may use configuration A or configuration B. The second part P2 may use configuration B and the first part P1 may use configuration A. In this way, the second part P2 may be given priority over the first part P1, and may be configured to not include a matching network 24, an inductor L (regardless of type) contained in a matching network 24, or a built-in inductor L contained in a matching network 24.

### 5. Example Structure of Composite Filter

The circuit configuration of the composite filter 1 described above may be realized using various structures. One example is described hereafter.

FIG. 6 is a schematic sectional view illustrating an example of the structure of the composite filter 1. This diagram is a schematic diagram, and therefore parts may be illustrated that are not actually located in the same cross-section. A Cartesian coordinate system xyz is added to FIG. 6 for convenience. Although the composite filter 1 can be used with any direction being regarded an upward direction, in the following description, for convenience, the +z side is sometimes expressed as the upper side.

The composite filter 1 is, for example, configured as a surface-mounted chip component. The overall shape is, for example, roughly a thin rectangular parallelepiped shape (a shape in which the thickness is smaller than the length of the short sides in plan view) with the vertical direction being the thickness direction. On the bottom surface of the composite filter 1, multiple external terminals 65 are provided for mounting the composite filter 1. The multiple external terminals 65 include, for example, the antenna terminal 5, the transmission terminal 7, and the reception terminal 9 described above, as well as a GND terminal to which a reference potential is applied. The GND terminal is an example of the reference potential portion 11 described above. Although not specifically illustrated, the composite filter 1 is mounted on a circuit board by bonding the multiple external terminals 65 to multiple pads on the circuit board using multiple conductive bumps (for example, solder).

The composite filter 1, for example, includes a multilayer substrate 61 and at least one (in the illustrated example, multiple) chip 63 fixed to the multilayer substrate 61. Although not specifically illustrated, the composite filter 1 may include an insulating sealing material (for example, resin) or an insulating cover that covers the illustrated configuration from the +z side. The sealing material or cover may or may not cover the side surfaces of the multilayer substrate 61.

The multilayer substrate 61, for example, constitutes the parts of composite filter 1 other than the transmission filter 13 and the reception filters 15. For example, the multilayer substrate 61 includes the following components (some of the components are not illustrated in FIG. 6). The external terminals 65 (in other words, the antenna terminal 5, the transmission terminal 7, the reception terminal 9, and the reference potential portion 11), the first hybrid 17, the second hybrid 19, the termination resistor 23, and the matching networks 24. Some of these components (for example, the termination resistor 23) may be provided in the chips 63. One or more chips 63, for example, constitute the transmission filter 13 and the reception filters 15.

The multilayer substrate 61 is, for example, formed in a roughly thin rectangular parallelepiped shape with the vertical direction being the thickness direction. The basic structure and materials of the multilayer substrate 61 (excluding the specific conductor patterns and dimensions, etc. for configuring the composite filter 1) may be the same as or similar to the structures and materials of various known printed boards. For example, the multilayer substrate 61 may be an LTCC (low temperature co-fired ceramics) substrate, a HTCC (high temperature co-fired ceramics) substrate, an IPD (integrated passive device) substrate, or an organic multilayer substrate.

An example of an LTCC substrate is one obtained by adding a glass-based material to alumina in order that the substrate can be sintered at a low temperature (for example, around 900° C.). Conductive materials such as Cu or Ag may be used in LTCC substrates. An example of an HTCC substrate is one made using a ceramic having alumina or aluminum nitride as a main component. For example, tungsten or molybdenum may be used as a conductive material in HTCC substrates. An example of an IPD substrate is one obtained by forming a passive element on or in a Si substrate. An example of an organic multilayer substrate is one obtained by stacking a prepreg impregnated with resin on a base material composed of glass etc.

The multilayer substrate 61, for example, includes a substantially insulating plate-shaped substrate 67 and conductors 69 positioned inside and/or on the surfaces of the substrate 67. The substrate 67 may include multiple insulating layers 67a stacked on top of each other, for example. The conductors 69 may, for example, include conductor layers 69a positioned on the main surfaces of the insulating layers 67a and via conductors 69b penetrating through the insulating layers 67a.

The chips 63 are, for example, configured as surface-mounted chip components. The overall shape of the chips 63 is, for example, roughly a thin rectangular parallelepiped shape with the thickness direction being the vertical direction. In the case where the transmission filter 13 and/or the reception filters 15 are acoustic wave filters, the basic structure and materials (configuration excluding specific conductor patterns and dimensions, etc.) of the chips 63 may be the same as or similar to the structure and materials of various known acoustic wave filter chips.

The chips 63 are disposed so as to face the top surface of the multilayer substrate 61. The chips 63 include terminals, which are not illustrated, on the surfaces thereof near the multilayer substrate 61. Although not specifically indicated by any symbols, the chips 63 are mounted on the multilayer substrate 61 by bonding the above-mentioned terminals and the pads, which are on the top surface of the multilayer substrate 61, to each other with conductive bumps (for example, solder).

The three filters (13 and 15) included in the composite filter 1 may be, for example, provided in separate chips 63 or in a common chip 63. In addition, two filters of the same type (for example, reception filters 15A and 15B) may be provided in a common chip 63, and the other filter may be provided in another chip 63. Furthermore, part of one filter and part of another filter may be provided in a common chip 63, and another part of the one filter and another part of the other filter may be provided in another common chip 63.

The first hybrid 17 and second hybrid 19 are, for example, incorporated into the multilayer substrate 61, and more specifically, built into the multilayer substrate 61. In other words, these hybrids are constituted by the conductors 69. Such built-in hybrids may be distributed constant or lumped constant hybrids. FIG. 6 illustrates an example of distributed constant type hybrids which each have a configuration consisting of two layers of coils that generally overlap each other. Regarding the elements that make up the lumped constant hybrids (for example, inductors and capacitors), the description of the elements that make up the matching networks 24 given below may be applied. Unlike in the illustrated example, the first hybrid 17 and/or the second hybrid 19 may be embedded in the multilayer substrate 61 or mounted on the multilayer substrate 61.

The inductors L, capacitors C, and/or resistors (not illustrated) that make up the matching networks 24 are, for example, incorporated into the multilayer substrate 61, and more specifically, built into the multilayer substrate 61. The specific configurations may be any configurations. For example, each inductor L may consist of meandering-shaped or spiral-shaped conductor patterns contained in the conductor layers 69a, or may consist of spiral-shaped conductors consisting of an appropriate combination of the conductor layers 69a and the via conductors 69b. The pair of electrodes of a capacitor may consist of the same conductor layers 69a, or may consist of different conductor layers 69a. Examples of the former case include a pair of strip-shaped electrodes that face each other in plan view, and a pair of comb electrodes that mesh with each other in plan view (see comb electrodes of acoustic wave resonator 29 described below). Examples of the latter case include flat plate electrodes that face each other with the insulating layer 67a therebetween in the thickness direction of the insulating layer 67a. Unlike in the above description, the elements constituting the matching networks 24 may be embedded in or mounted on the multilayer substrate 61.

The composite filter 1 may be part of a module rather than a chip component as in the illustrated example. In more detail, for example, the multilayer substrate 61 may have a larger area than in the illustrated example, or may include elements (electronic components), which are not included in the composite filter 1, that are mounted on or incorporated into the multilayer substrate 61. In such a case, the composite filter 1 may be connected to other elements by wiring lines consisting of the conductors 69 of the multilayer substrate 61. From another perspective, there do not need to be any portions that clearly match the concept of the terminals of the composite filter 1 (5, 7, and 9, and the GND terminal as an example of the reference potential portion 11). For example, an IC (integrated circuit) and an antenna can be given as examples of elements to be mounted on or incorporated into the multilayer substrate 61.

### 6. Example Configurations of Transmission Filter and Reception Filters 15

As previously mentioned, the transmission filter 13 and/or the reception filters 15 may be acoustic wave filters that utilize acoustic waves. An example of the configuration of an acoustic wave filter will be described below.

### (6.1. Example of Acoustic Wave Element)

FIG. 7 is a plan view schematically illustrating the configuration of an acoustic wave resonator 29 (hereafter may be simply referred to as “resonator 29”) as an example of an acoustic wave element included in an acoustic wave filter.

Although any direction may be regarded as being up or down in relation to the resonator 29, hereafter, for convenience, a Cartesian coordinate system consisting of D1, D2, and D3 axes is added to the drawing, and the +D3 side (side in front of the page) may be regarded as an upper side, and terms such as top surface or bottom surface may be used. The D1 axis is defined as parallel to the propagation direction of acoustic waves propagating along the top surface of a piezoelectric body, which is described later, the D2 axis is defined as parallel to the top surface of the piezoelectric body and perpendicular to the D1 axis, and the D3 axis is defined as perpendicular to the top surface of the piezoelectric body.

The resonator 29 is configured as a so-called one-port acoustic wave resonator. The resonator 29, for example, outputs a signal input from one of two terminals 28, which are illustrated schematically on both sides of the drawing, from the other of the two terminals 28. In this case, the resonator 29 converts an electrical signal to acoustic waves and converts acoustic waves to an electrical signal. As can be understood from the description of FIG. 8 below, the terminals 28 may, for example, correspond to any one of the antenna terminal 5, the transmission terminal 7, the reception terminal 9, and the reference potential portion 11.

The resonator 29 includes, for example, the piezoelectric property substrate 31 (at least a portion on the top surface 31a side), an excitation electrode 33 positioned on the top surface 31a, and a pair of reflectors 35 located on both sides of the excitation electrode 33. A configuration obtained by removing the pair of reflectors 35 from the resonator 29 (one-port resonator) is also a type of resonator.

Multiple resonators 29 may be configured on a single piezoelectric property substrate 31. In other words, the piezoelectric property substrate 31 may be shared by multiple resonators 29. In the following description, in order to distinguish between multiple resonators 29 that share the same piezoelectric property substrate 31, for convenience, the combination of the excitation electrode 33 and the pair of reflectors 35 (the electrode portion of the resonator 29) may be described as through this combination were the resonator 29 (as though the resonator 29 does not include the piezoelectric property substrate 31).

The piezoelectric property substrate 31 has a piezoelectric property in at least the region of the top surface 31a where the resonator 29 is provided. Such a piezoelectric property substrate 31 can be, for example, one in which the entire substrate is composed of a piezoelectric material. In addition, for example, a so-called laminated substrate can be mentioned. A laminated substrate includes a substrate composed of a piezoelectric material having the top surface 31a (piezoelectric substrate) and a support substrate attached directly to the surface of the piezoelectric substrate on the opposite side from the top surface 31a either with an adhesive or without an adhesive therebetween. The support substrate may have a recess in the top surface thereof to form a cavity that overlaps at least part of the resonator 29 in planar perspective view, or may not have such a recess. Furthermore, the piezoelectric property substrate 31 can consist of, for example, a support substrate and a film composed of a piezoelectric material (piezoelectric film) or a plurality of films including a piezoelectric film formed on a partial region of a main surface of the support substrate on the +D3 side or on the entirety of the main surface.

The piezoelectric body 31b, which constitutes at least the region of the piezoelectric property substrate 31 where the resonator 29 is provided, is composed of, for example, a single crystal having a piezoelectric property. Examples of materials that constitute such a single crystal include, for example, lithium tantalate (LiTaO₃), lithium niobate (LiNbO₃), and quartz (SiO₂). The cut angle, planar shape, and various dimensions may be set as appropriate.

The excitation electrode 33 and the reflectors 35 are composed of layer conductors provided on the piezoelectric property substrate 31. The excitation electrode 33 and the reflectors 35 may be composed of the same material and have the same thickness as each other, for example. The layer conductors constituting these electrodes are, for example, composed of a metal. The metal is, for example, Al or an alloy having Al as a main component (Al alloy). The Al alloy is, for example, an Al—Cu alloy. The layer conductor may be formed of a plurality of metal layers. The thickness of the layer conductors is set as appropriate depending on the electrical characteristics etc. required for the resonator 29. As an example, the thickness of the layer conductors is greater than or equal to 50 nm and less than or equal to 600 nm.

The excitation electrode 33 is composed of a so-called IDT (interdigital transducer) electrode and includes a pair of comb electrodes 37 (one of which is hatched for improved visibility). Each comb electrode 37 includes, for example, a busbar 39, multiple electrode fingers 41 extending parallel to each other from the busbar 39, and multiple dummy electrodes 43 protruding from the busbar 39 between the multiple electrode fingers 41. The pair of comb electrodes 37 are disposed so that the multiple electrode fingers 41 mesh with each other (cross each other).

The busbars 39 are, for example, formed in a generally long shape having a constant width and extending in a straight line in the propagation direction of acoustic waves (D1 direction). The pair of busbars 39 face each other in a direction (D2 direction) perpendicular to the propagation direction of acoustic waves. The busbars 39 may vary in width or be inclined with respect to the propagation direction of acoustic waves.

Each electrode finger 41 is, for example, formed in a generally long shape having a constant width and extending in a straight line in a direction (D2 direction) perpendicular to the propagation direction of acoustic waves. The width of the electrode fingers 41 may vary. In each comb electrode 37, the multiple electrode fingers 41 are arranged in the acoustic wave propagation direction. The multiple electrode fingers 41 of one comb electrode 37 and the multiple electrode fingers 41 of the other comb electrode 37 are basically arranged in an alternating manner with respect to each other.

A pitch p of the multiple electrode fingers 41 (for example, the distance between the centers of two adjacent electrode fingers 41) is basically constant within the excitation electrode 33. Note that the excitation electrode 33 may include some parts that are different in terms of the pitch p. Examples of such different parts include, for example, small pitch parts where the pitch p is smaller than that of the majority (for example, 80% or more) of the electrode fingers 41, large pitch parts where the pitch p is larger than that of the majority of the electrode fingers 41, and thinned parts where a small number of electrode fingers 41 have been substantially thinned out.

Hereafter, when the pitch p is referred to, unless otherwise specified, the pitch p refers to the pitch of the parts (majority of the plurality of electrode fingers 41) excluding the different parts described above. In addition, in the case where the pitch changes even in the majority of the plurality of electrode fingers 41 excluding the different parts, the average value of the pitch of the majority of the plurality of electrode fingers 41 may be used as the value of the pitch p.

The number of electrode fingers 41 may be set as appropriate in accordance with the electrical characteristics etc. required for the resonator 29. FIG. 7 is a schematic diagram, and therefore a small number of the electrode fingers 41 are illustrated. In reality, a greater number of electrode fingers 41 may be arranged than is illustrated in the figure. This also applies to strip electrodes 47 of the reflectors 35 described below.

The multiple electrode fingers 41 have the same lengths as each other, for example. In addition, the excitation electrode 33 may be subjected to so-called apodization, in which the length (or, from another perspective, a crossing width W) of the multiple electrode fingers 41 changes depending on the position in the propagation direction. The lengths and widths of the electrode fingers 41 may be set as appropriate in accordance with the required electrical characteristics, etc.

The dummy electrodes 43, for example, generally have a constant width and protrude in a direction perpendicular to the propagation direction of acoustic waves. This width is, for example, identical to the width of the electrode fingers 41. The multiple dummy electrodes 43 are arranged at the same pitch as the multiple electrode fingers 41, and the tips of the dummy electrodes 43 of one comb electrode 37 face the tips of the electrode fingers 41 of the other comb electrode 37 across a gap. Note that the excitation electrode 33 does not need to include the dummy electrodes 43.

The pair of reflectors 35 are positioned on both sides of the excitation electrode 33 in the propagation direction of acoustic waves. Each reflector 35 may be electrically floating or supplied with a reference potential, for example. Each reflector 35 is formed in the shape of a lattice, for example. In other words, each reflector 35 includes a pair of busbars 45 facing each other and multiple strip electrodes 47 extending between the pair of busbars 45. The pitch of the multiple strip electrodes 47 and the pitch between the electrode fingers 41 and the strip electrodes 47 that are adjacent thereto are basically equivalent to the pitch of the multiple electrode fingers 41, for example.

When a voltage is applied to the pair of comb electrodes 37, a voltage is applied to the piezoelectric body 31b by the multiple electrode fingers 41 and the piezoelectric body 31b vibrates. In other words, acoustic waves are excited. Among acoustic waves of various wavelengths propagating in various directions, acoustic waves propagating in the arrangement direction of the multiple electrode fingers 41 with the pitch p of the multiple electrode fingers 41 being approximately half the wavelength (λ/2) tend to have a larger amplitude because multiple waves excited by the multiple electrode fingers 41 overlap in phase with each other.

The acoustic waves propagating through the piezoelectric body 31b are converted into an electrical signal by the multiple electrode fingers 41. At this time, similarly to as when the acoustic waves are excited, the strength of an electrical signal converted from acoustic waves propagating in the arrangement direction of the multiple electrode fingers 41 with the pitch p of the multiple electrode fingers 41 approximately half the wavelength (λ/2) tends to be higher.

As a result of the above operation (and other operations not described here), the resonator 29 functions as a resonator whose resonance frequency is, for example, the frequency of an acoustic wave whose half wavelength (λ/2) is approximately equal to the pitch p. The pair of reflectors 35 contributes to confining the acoustic waves.

In the above description, acoustic waves propagating in the arrangement direction of the multiple electrode fingers 41 has been taken as an example, but acoustic waves may also propagate in the thickness direction of the piezoelectric body 31b. For example, thickness shear waves in which the piezoelectric body 31b vibrates so that the top surface and the bottom surface slide relative to each other may be used. In this case, a cavity may be provided between the bottom surface of the piezoelectric body 31b and the support substrate that supports the piezoelectric body 31b. The wavelength is highly dependent on the thickness of the piezoelectric body 31b, and is less dependent on the pitch p. The reflectors 35 may be omitted.

Although not specifically illustrated, the resonator 29 may include a protective film, which is not illustrated, that covers the top surface 31a of the piezoelectric property substrate 31 from above the excitation electrode 33 and the reflectors 35. Such a protective film is, for example, composed of an insulating material such as SiO₂, and contributes to reducing the probability of the excitation electrode 33 etc. corroding and/or compensating for changes in characteristics caused by temperature changes in the resonator 29. In addition, the resonator 29 may include an additional film that overlaps the top surface or bottom surface of the excitation electrode 33 and the reflectors 35, and has a shape that basically fits within the excitation electrode 33 and reflectors 35 in planar perspective view. Such an additional film is, for example, composed of an insulating material or metal material having different acoustic properties from the material of the excitation electrode 33, and contributes to improving the reflection coefficient of acoustic waves.

Each chip 63 illustrated in FIG. 6 may be mainly composed of the piezoelectric property substrate 31, for example. For example, the chip 63 may be a bare chip basically consisting of only the configuration described with reference to FIG. 7. The +D3-side surface of the piezoelectric property substrate 31 is made to face the top surface of the multilayer substrate 61, and layer-shaped terminals, which are not illustrated, positioned on the top surface of the piezoelectric property substrate 31 and pads positioned on the top surface of the multilayer substrate 61 are bonded to each other using bumps. For example, the chip 63 may be a wafer-level package (WLP) type chip with a cover, which is not illustrated, that covers the +D3-side surface of the piezoelectric property substrate 31. The top surface of the cover (the surface on the +D3 side) is positioned so as to face the top surface of the multilayer substrate 61, and pillar-shaped terminals, which are not illustrated, that penetrate through the cover and pads positioned on the top surface of the multilayer substrate 61 are bonded to each other using bumps. In addition, for example, the chip 63 may be a FO (fan out)-WLP type chip with a molded part covering the side surfaces of the bare chip.

### (6.2. Example Configuration of Splitter Body Using Acoustic Wave Filter)

FIG. 8 is a circuit diagram schematically illustrating the configuration of the splitter body 3 (parts directly contributing filtering including the transmission filter 13 and reception filters 15). In this figure, only the splitter body 3 and the terminals of the composite filter 1 are illustrated. In other words, illustration of the first hybrid 17, the second hybrid 19 and so on is omitted. In addition, only one of the reception filters 15A and 15B is illustrated.

In this figure, the comb electrodes 37 are each schematically illustrated in the shape of a two-pronged fork, and the reflectors 35 are each represented by a single line bent at both ends, as indicated by the symbols in the upper left corner of the figure. In the following description, the term “splitter body 3” may be replaced with the term “composite filter 1” so long as there are no contradictions.

The splitter body 3 includes the antenna terminal 5, the transmission terminal 7, the reception terminal 9, the reference potential portion 11, the transmission filter 13, and the reception filter 15, as described above. The antenna terminal 5 and the filters (13 and 15) are connected to each other via the first hybrid 17. In FIG. 8, for convenience, the first hybrid 17 is omitted and the connection between the antenna terminal 5 and the filters is illustrated as a broken line. In addition, the reception terminal 9 and the reception filter 15 are connected to each other via the second hybrid 19. In the following description, for convenience, the connection relationship may be described as through the hybrids (17 and 19) were not provided.

The transmission filter 13 is, for example, configured as a ladder filter consisting of multiple resonators 29 (29S and 29P) connected in a ladder configuration. In other words, the transmission filter 13 includes multiple (or just one) series resonators 29S connected in series with each other between the transmission terminal 7 and the antenna terminal 5, and multiple (or just one) parallel resonators 29P (parallel arms) connecting the series line (series arm) to the reference potential portion 11.

The reception filter 15 includes, for example, the resonator 29 and a multi-mode filter 49 (which is assumed to include a double-mode filter. Hereafter may be referred to as MM filter 49). The MM filter 49 includes multiple (three in the illustrated example) excitation electrodes 33 arranged in the propagation direction of acoustic waves and a pair of reflectors 35 disposed on both sides of the excitation electrodes 33.

The configuration of the transmission filter 13 and the reception filter 15 is just an example, and may be modified as appropriate. For example, the reception filter 15 may be configured as a ladder filter in the same or a similar manner to the transmission filter 13, or conversely, the transmission filter 13 may include the MM filter 49.

### 7. Example of Communication Device Including Composite Filter

The composite filter may be used in a communication module or a communication device, for example. One example is described hereafter.

FIG. 9 is a block diagram illustrating the main components of a communication device 151 as an example use of the composite filter 1. The communication device 151 includes a module 171 and a housing 173 that houses the module 171. The module 171 performs wireless communication using radio waves and includes the composite filter 1. In this diagram, only the transmission filter system 12 and reception filter system 14 of the composite filter 1 are illustrated and illustration of the hybrids etc. is omitted.

In the module 171, a transmission information signal TIS, which contains information to be transmitted, is modulated and raised in frequency (converted to a radio-frequency signal having a carrier frequency) by an RF-IC (radio frequency integrated circuit) 153, and becomes a transmission signal TS. Unwanted components outside a transmission passband are removed from the transmission signal TS by a bandpass filter 155, and the resulting transmission signal TS is then amplified by an amplifier 157 and input to the composite filter 1 (transmission terminal 7). The composite filter 1 (transmission filter system 12) removes unwanted components outside the transmission passband from the input transmission signal TS, and then outputs the resulting transmission signal TS from the antenna terminal 5 to an antenna 159. The antenna 159 converts the input electrical signal (transmission signal TS) into a radio signal (radio waves) and transmits the radio signal.

In the module 171, a radio signal (radio waves) received by the antenna 159 is converted into an electrical signal (reception signal RS) by the antenna 159 and input to the composite filter 1 (antenna terminal 5). The composite filter 1 (reception filter system 14) removes unwanted components outside a reception passband from the input reception signal RS and outputs the resulting reception signal RS from the reception terminal 9 to an amplifier 161. The output reception signal RS is amplified by the amplifier 161, and unwanted components outside the reception passband are removed by a bandpass filter 163. The reception signal RS is then reduced in frequency and demodulated by the RF-IC 153, and becomes a reception information signal RIS.

The transmission information signal TIS and the reception information signal RIS may be low-frequency signals (baseband signals) containing appropriate information, for example, analog or digitized audio signals. The radio signal passband may be set as appropriate. The modulation method may be phase modulation, amplitude modulation, frequency modulation, or a combination of any two or more of these methods. Although the direct conversion method is illustrated, other types of circuit may be used as appropriate, for example, a double superheterodyne type circuit. FIG. 9 is a diagram schematically illustrating only the main parts, and a low-pass filter, an isolator, and so on may be added at appropriate positions, and the positions of amplifiers and so on may be changed.

The module 171, for example, includes the components from the RF-IC 153 to the antenna 159 on the same circuit board. In other words, the composite filter 1 is modularized by being combined with other components. The circuit board may be the multilayer substrate 61, or may be one on which the multilayer substrate 61 (composite filter 1) is mounted. The composite filter 1 may be included in the communication device 151 without being modularized. The components illustrated as components of the module 171 may be positioned outside of the module or not housed in the housing 173. For example, the antenna 159 may be exposed outside the housing 173.

### 8. Summary of Embodiments

As described above, the composite filter 1 (or 201 or 301) includes the first hybrid 17, a first filter (for example, the transmission filter 13 of the First Embodiment), and second and third filters (for example, the reception filters 15A and 15B of the First Embodiment). The first hybrid 17 is configured by a 90° hybrid coupler that includes a first port and a second port (port 17a and port 17b), and a third port and a fourth port (port 17c and port 17d) to which signals input to the port 17a or the port 17b are distributed. The first filter is connected to the port 17b and has a first passband (for example, the transmission band in the First Embodiment). The second filter is connected to the port 17c and has a second passband (for example, reception band in the First Embodiment) that does not overlap the first passband. The third filter is connected to the port 17d and has the second passband. An electrical section from the first filter to the first hybrid 17 (first section 10A) will be referred to as the first part P1. The combination of an electrical section from the second filter to the first hybrid 17 (second section 10B) and an electrical section from the third filter to the first hybrid 17 (third section 10C) will be referred to as the second part P2. Here, at least one of the first part P1 or the second part P2 does not include a matching network containing an inductor including a conductor of a multilayer substrate (in other words, a built-in inductor).

Therefore, as mentioned above, the probability of insertion loss occurring due to an inductor with a low Q value can be reduced, and the pass characteristics can be improved. In the preceding paragraph, the term “multilayer substrate” in the statement “inductor including a conductor of a multilayer substrate” does not refer to a specific multilayer substrate (for example, the multilayer substrate 61), but rather to multilayer substrates in general. In other words, the composite filter 1 including the multilayer substrate 61 is not a prerequisite of the configuration described in the preceding paragraph.

At least one of the first part P1 or the second part P2 does not need to include a matching network containing an inductor L (regardless of whether or not the inductor is a built-in inductor).

In this case, for example, as a result of inductors (mounted or embedded) with a relatively high Q value not being provided, the probability of insertion loss occurring can be further reduced and the pass characteristics can be improved.

The second part P2 does not need to include a matching network.

In this case, for example, by not providing any matching network in the second part P2, the probability of insertion loss occurring can be further reduced and the pass characteristics can be improved. In addition, as described with reference to FIGS. 2 and 3, the matching network of the second part P2 affects the reflection characteristics when a signal of the first passband (for example, the transmission signal in the First Embodiment) is input to the second filter and the third filter (for example, the reception filters 15A and 15B) having the second passband, and this leads to not only a simple reduction in insertion loss due to the presence of the matching network 24, but also a reduction in insertion loss due to reduction of the reflection characteristics. Furthermore, a signal in the first passband passes through the first part P1 only once, from the first filter (e.g., the transmission filter 13 in the First Embodiment) to the first hybrid 17, whereas the signal in the first passband passes through the second part P2 twice, once when the signal travels from the first hybrid 17 to the second and third filters, and once when the signal is reflected by the second and third filters and travels back to the first hybrid 17. For the above reasons, the matching network 24 in the second part P2 has a greater effect on degradation of the pass characteristics than the matching network 24 in the first part P1. By not providing the matching network 24 in the second part P2, the effect of improving the pass characteristics due to the absence of the matching network 24 is improved.

In addition to the fact that the second part P2 does not include a matching network (of any type), the first part P1 does not need to include a matching network (of any type) (refer to FIG. 4).

In this case, for example, because there is no matching network 24 between the three filters and the first hybrid 17, the effect of improving the pass characteristics resulting from not providing a matching network 24 is further improved.

At least one of the first part P1 or the second part P2 may include the matching network 24 containing the capacitor C (see FIG. 5).

In this case, for example, by using the capacitor C that allows high-frequency components to pass therethrough, impedance matching can be realized while reducing insertion loss.

The composite filter 1 may include a matching network 24 electrically connected to the opposite side of a second filter (for example, the reception filter 15A of the First Embodiment) from the side to which the first hybrid 17 is connected, and a matching network 24 electrically connected to the opposite side of a third filter (for example, the reception filter 15B of the First Embodiment) from the side to which the first hybrid 17 is connected.

In this case, for example, as already mentioned, impedance matching can be achieved using the matching network 24 of the third part P3 while obtaining the effect of improving the pass characteristics by not providing a matching network 24 in at least one of the first part P1 or the second part P2 (particularly the second part P2), and the pass characteristics can be further improved.

The composite filter 1 may include a common terminal (the antenna terminal 5), a first terminal (for example, the transmission terminal 7 in the First Embodiment), the second hybrid 19, a second terminal (for example, the reception terminal 9 in the First Embodiment), and the termination resistor 23. The antenna terminal 5 may be connected to a first port (port 17a). The first terminal may be electrically connected to the opposite side of the first filter (for example, the transmission filter 13 in the First Embodiment) from the side to which the first hybrid 17 is connected. The second hybrid 19 may be configured by a 90° hybrid coupler including fifth to eighth ports (ports 19a to 19d). The port 19a may be electrically connected to the opposite side of the second filter (for example, the reception filter 15A in the First Embodiment) from the side to which the first hybrid 17 is connected. The port 19b may be electrically connected to the opposite side of the third filter (for example, the reception filter 15B in the First Embodiment) from the side to which the first hybrid 17 is connected. The ports 19c and 19d distribute signals from the port 19a or 19b. The second terminal may be connected to one of the ports 19c and 19d (port 19d in FIG. 1, etc.) where a signal passing through the ports 17a, 17c, and 19a in this order and a signal passing through the ports 17a, 17d, and 19b in this order are in phase with each other. The termination resistor 23 may be connected to another port from among the ports 19c and 19d.

In this case, for example, nonlinear distortion can be reduced, as previously described. Note that in the preceding paragraphs, we stated that signals input to the port 19a or 19b are distributed to ports 19c and 19d as a convenience for describing the relationship between the fifth to eighth ports (ports 19a through 19d), and in reality, the intended signals do not need to be input to the port 19a or 19b (see FIG. 4). Similarly, as a convenience for describing the relationship between the fifth to eighth ports (ports 19a to 19d), we stated that the signal input to the first port (port 17a) has the same phase at the port 19d, and in reality, the intended signal does not need to reach the port 19d from the port 17a (see FIG. 4).

The composite filter 1 may include a first substrate (the multilayer substrate 61) composed of a multilayer substrate, and the chip 63 that is mounted on the multilayer substrate 61 and includes at least one acoustic wave filter. The at least one acoustic wave filter may include at least one selected from the group consisting of the first filter, the second filter, and the third filter (e.g., transmission filter 13 and reception filters 15A and 15B in the First Embodiment).

In this case, for example, nonlinear distortion that occurs in an acoustic wave filter can be reduced using a hybrid. The hybrid is incorporated into or mounted on the multilayer substrate 61, and as a result, the composite filter 1 having a compact configuration with the chip 63 of an acoustic wave filter mounted on the multilayer substrate 61 is realized. Unlike in the embodiment, the inductors L of the matching networks 24 in the first part P1 and the second part P2 can be built into the multilayer substrate 61 to realize a further reduction in size. However, deliberately not adopting such a configuration allows the pass characteristics to be improved.

The composite filter 301 includes, from another perspective, the first hybrid 17, a first filter (e.g., the transmission filter 13), a second filter (e.g., the reception filter 15A), and a third filter (e.g., the reception filter 15B). The first hybrid 17 is configured by a 90° hybrid coupler that includes a first port and a second port (port 17a and port 17b), and a third port and a fourth port (port 17c and port 17d) to which a signal (for example, transmission signal) input to the port 17a or the port 17b is distributed. The first filter is connected to the port 17b and has a first passband (for example, the transmission band). The second filter is connected to the port 17c and has a second passband (for example, the reception band) that does not overlap the first passband. The third filter is connected to the port 17d and has the second passband. An electrical section from the first filter to the first hybrid 17 (first section 10A) will be referred to as the first part P1. The combination of an electrical section from the second filter to the first hybrid 17 (second section 10B) and an electrical section from the third filter to the first hybrid 17 (third section 10C) will be referred to as the second part P2. At this time, at least one of the first part P1 or the second part P2 includes the matching network 24 containing the capacitor C.

In this case, for example, by using the capacitor C that allows high-frequency components to pass therethrough, impedance matching can be realized while reducing insertion loss. The symbols of the Third Embodiment are used in the preceding paragraphs, but the possibility of applying the above configurations to other embodiments has already been mentioned.

The communication device 151 may include the composite filter 1 (or 201 or 301), the antenna 159 connected to a first port (port 17a), and an integrated circuit element (RF-IC 153) electrically connected to the opposite side of each of the first filter, the second filter, and the third filter from the side connected to the first hybrid 17.

In this case, for example, the communication device 151 can utilize the effect of the improved pass characteristics in the composite filter 1 described above. In turn, the communication characteristics are improved.

In the above-described embodiments, the antenna terminal 5 is an example of a common terminal. In the First Embodiment and Third Embodiment, the transmission filter 13 is an example of a first filter, the reception filters 15A and 15B are examples of a second filter and a third filter, respectively, the transmission terminal 7 is an example of a first terminal, and the reception terminal 9 is an example of a second terminal. In the Second Embodiment, the reception filter 15 is an example of a first filter, the transmission filters 13A and 13B are examples of a second filter and a third filter, respectively, the reception terminal 9 is an example of a first terminal, and the transmission terminal 7 is an example of a second terminal. The multilayer substrate 61 is an example of a first substrate. The ports 17a to 17d and 19a to 19d are examples of first to eighth ports, respectively. The RF-IC 153 is an example of an integrated circuit element.

Technologies according to the present disclosure are not limited to the above embodiments and may be implemented in the form of various modes.

For example, the composite filter 1 may include only the configuration on the second and third filter side from the third part P3 in the composite filter 1, 201 or 301. The configuration on the right side of FIG. 1, FIG. 4 and FIG. 5 from the third part P3 may be external to the composite filter 1.

The composite filter 1 may be part of a multiplexer, such as a triplexer or quadplexer. The composite filter 1 is not limited to a duplexer, and may be a diplexer (multiplexer) that filters two transmission signals or two reception signals whose frequencies (frequency bands) are different from each other.

The composite filter does not need to include a multilayer substrate. For example, a composite filter may be configured by mounting filters or hybrids on a single-sided or double-sided substrate.

### REFERENCE SIGNS

1, 201, 301 composite filter, 13,13A, 13B transmission filter (first filter, second filter, or third filter), 15, 15A, 15B reception filter (first filter, second filter, or third filter), 17 first hybrid, 17a first port, 17b second port, 17c third port, 17d fourth port.

1. A composite filter comprising:
a first hybrid including a 90° hybrid coupler including a first port and a second port and a third port and a fourth port to which a signal input to the first or second port is distributed;
a first filter connected to the second port and having a first passband;
a second filter connected to the third port and having a second passband that does not overlap the first passband; and
a third filter connected to the fourth port and having the second passband,
wherein when a first part is an electrical section from the first filter to the first hybrid, and
a second part is a combination of an electrical section from the second filter to the first hybrid and an electrical section from the third filter to the first hybrid,
at least one of the first part or the second part does not include a matching network containing an inductor including a conductor of a multilayer substrate.

2. The composite filter according to claim 1, wherein at least one of the first part or the second part does not include a matching network containing an inductor.

3. The composite filter according to claim 2, wherein the second part does not include a matching network.

4. The composite filter according to claim 3, wherein the first part does not include a matching network.

5. The composite filter according to claim 1, wherein at least one of the first part or the second part includes a matching network containing a capacitor.

6. The composite filter according to claim 1, further comprising:
a matching network electrically connected to an opposite side of the second filter from a side of the second filter to which the first hybrid is connected, and
a matching network electrically connected to an opposite side of the third filter from a side of the third filter to which the first hybrid is connected.

7. The composite filter according to claim 1, further comprising:
a common terminal connected to the first port;
a first terminal electrically connected to an opposite side of the first filter from a side of the first filter to which the first hybrid is connected;
a second hybrid including a 90° hybrid coupler including a fifth port electrically connected to an opposite side of the second filter from a side of the second filter to which the first hybrid is connected, a sixth port electrically connected to an opposite side of the third filter from a side of the third filter to which the first hybrid is connected, and a seventh port and a eighth port to which a signal from the fifth port or the sixth port is distributed;
a second terminal connected to a port that is one port among the seventh port and the eighth port and at which a signal that passes through the first port, the third port, and the fifth port in that order and a signal that passes through the first port, the fourth port, and the sixth port in that order are in phase with each other, and
a termination resistor connected to another port among the seventh port and the eighth port.

8. The composite filter according to claim 1, further comprising:
a first substrate composed of a multilayer substrate; and
a chip mounted on the first substrate and containing at least one acoustic wave filter,
wherein the at least one acoustic wave filter includes at least one selected from a group consisting of the first filter, the second filter and the third filter.

9. A composite filter comprising:
a first hybrid including a 90° hybrid coupler including a first port and a second port and a third port and a fourth port to which a signal input to the first or second port is distributed;
a first filter connected to the second port and having a first passband;
a second filter connected to the third port and having a second passband that does not overlap the first passband; and
a third filter connected to the fourth port and having the second passband,
wherein when a first part is an electrical section from the first filter to the first hybrid, and
a second part is a combination of an electrical section from the second filter to the first hybrid and an electrical section from the third filter to the first hybrid,
at least one of the first part or the second part includes a matching network containing a capacitor.

10. A communication device comprising:
the composite filter according to claim 1;
an antenna connected to the first port; and
an integrated circuit element electrically connected to an opposite side of each of the first filter, the second filter, and the third filter from the first hybrid.
